(19) United States
(12) Patent Application Publication
(10) Pub. No.: US 2025/0201697 A1
(43) Pub. Date: Jun. 19, 2025

(54) TWO-DIMENSIONAL LAYER ASSISTED THREE-DIMENSIONAL TOP VIA INTERCONNECTS

(71) Applicant: International Business Machines Corporation, Armonk, NY (US)

(72) Inventors: Koichi Motoyama, Clifton Park, NY (US); Kisik Choi, Watervliet, NY (US); Christopher J. Penny, Saratoga Springs, NY (US); Hosadurga Shobha, Niskayuna, NY (US); Ruilong Xie, Niskayuna, NY (US)

(21) Appl. No.: 18/539,618

(22) Filed: Dec. 14, 2023

(51) Int. Cl. H01L 23/522; H01L 21/768; H01L 23/528; H01L 23/532

(52) U.S. Cl. CPC H01L 23/5226; H01L 21/76841; H01L 23/5283; H01L 23/53266

(57) ABSTRACT

A low line and via resistance interconnect structure is provided in which two-dimensional material is continuously present along the sidewalls of via of a top via structure and an upper line structure. A portion of the two-dimensional material is located on physically exposed surfaces of the line of the top via structure.

### BACKGROUND

The present application relates to semiconductor technology, and more particularly to an interconnect structure having low line and via resistance, and a method of forming the same.

Generally, back-end-of-the-line (BEOL) interconnect structures include a plurality of circuits which form an integrated circuit fabricated on a BEOL interconnect substrate. A complex network of signal paths will normally be routed to connect the circuit elements distributed on the surface of the substrate. Efficient routing of these signals across the device requires formation of multilevel or multilayered schemes, such as, for example, single or dual damascene wiring, i.e., interconnect, structures. Within typical BEOL interconnect structures, electrically conductive metal vias run perpendicular to the BEOL interconnect substrate and electrically conductive metal lines run parallel to the BEOL interconnect substrate. Typically, the electrically conductive metal vias are present beneath the electrically conductive metal lines and both features are embedded within an interconnect dielectric material layer.

BEOL interconnect structures using top via structures appear to be defining the next generation technology roadmap for scaling with better RC performance. RC is the product of resistance, R, and capacitance, C, which needs to be low to create fast chips since device speed is inversely proportional to RC (lower RC generally provides faster devices).

### SUMMARY

A low line and via resistance interconnect structure is provided in which two-dimensional material is continuously present along the sidewalls of via of a top via structure and an upper line structure. A portion of the two-dimensional material is located on physically exposed surfaces of the line of the top via structure.

In one aspect of the present application, an interconnect structure is provided. In an embodiment of the present application, the interconnect structure includes a top via structure including a via located on a line. An upper line structure is located on top of the via and orientated perpendicular to the line of the top via structure. A first two dimensional (2D) material layer is located along sidewalls of the top via structure and on a topmost surface of the line of the top via structure, and a second 2D material layer is located along sidewalls and a topmost surface of the upper line structure In the interconnect structure, the first 2D material layer and the second 2D material layer contact each other along the sidewalls of the top via structure and the upper line structure.

In another embodiment, the interconnect structure includes a top via structure including a via located on a line, wherein the via and line are composed of an electrically conductive material. The structure of this embodiment also includes an upper line structure located on top of the via and orientated perpendicular to the line of the top via structure, and a continuous 2D material covers an entirety of the upper line structure and the top via structure.

In yet another embodiment, the interconnect structure includes a top via structure comprising a via located on a line, wherein the via and line are composed of a non-conductive material. The structure of this embodiment further includes an upper line structure located on top of the via and orientated perpendicular to the line of the top via structure and a continuous 2D material covering an entirety of the upper line structure and the top via structure.

In another aspect of the present application a method of forming an interconnect structure is provided. In an embodiment of the present application, the method includes forming a first 2D material layer on physically exposed surfaces of a top via structure, the top via structure including a via located on a line. Next, dielectric layer is formed adjacent to the top via structure. After dielectric layer formation, an upper line structure is formed on top of the via of the top via structure, and thereafter, a second 2D material layer is formed on physically exposed surfaces of the upper line structure. In the method of the present application, the first 2D material layer and the second 2D material layer contact each other along sidewalls of the top via structure and the upper line structure.

### BRIEF DESCRIPTION OF THE DRAWINGS

FIGS. 1A, 1B and 1C are various views (i.e., top down, Y—Y cross section and 3D) of an exemplary structure that can be employed in the present application, the initial structure including a pair line structures sandwiching a top via structure.

FIGS. 2A, 2B and 2C are various views of the exemplary structure shown in FIGS. 1A, 1B and 1C, respectively, after forming a first 2D material layer on the pair of line structures and the top via structure.

FIGS. 3A, 3B and 3C are various views of the exemplary structure shown in FIGS. 2A, 2B and 2C, respectively, after forming a dielectric layer.

FIGS. 4A, 4B and 4C are various views of the exemplary structure shown in FIGS. 3A, 3B and 3C, respectively, after revealing a topmost surface of the top via structure.

FIGS. 5A, 5B and 5C are various views of the exemplary structure shown in FIGS. 4A, 4B and 4C, respectively, after forming a diffusion barrier layer and a template material layer.

FIGS. 6A, 6B and 6C are various views of the exemplary structure shown in FIGS. 5A, 5B and 5C, respectively, after patterning the diffusion barrier layer and template material layer to provide a diffusion barrier liner and upper line structure; in this exemplified embodiment there is no mis-alignment issue between the via of the top via structure and the upper line structure.

FIGS. 7A, 7B and 7C are various views of the exemplary structure shown in FIGS. 6A, 6B and 6C, respectively, after forming a second 2D material layer to provide an interconnect structure in accordance with one embodiment of the present application.

FIG. 8 is a skeleton image of the interconnect structure shown in FIG. 7C without the dielectric layer.

FIGS. 9A, 9B and 9C are various views of the exemplary structure shown in FIGS. 5A, 5B and 5C, respectively, after patterning the diffusion barrier layer and a template material layer to provide a diffusion barrier liner and upper line structure; in this exemplified embodiment there is some mis-alignment issue between the via of the top via structure and the upper line structure.

FIGS. 10A, 10B and 10C are various views of the exemplary structure shown in FIGS. 9A, 9B and 9C, respectively, after forming a second 2D material layer to provide an interconnect structure in accordance with another embodiment of the present application.

FIG. 11 is a skeleton image of the interconnect structure shown in FIG. 10C without the dielectric layer.

FIGS. 12A, 12B and 12C are various views (i.e., top down, Y—Y cross section and 3D) of another exemplary structure that can be employed in the present application, the another exemplary structure including a pair line structures sandwiching a top via structure, in this embodiment the top via structure has an elongated via as compared to the via of the top via structure shown in FIGS. 1A, 1B and 1C.

FIGS. 13A, 13B and 13C are various views of the exemplary structure shown in FIGS. 12A, 12B and 12C, respectively, after performing the processing steps shown in FIGS. 2A-6C above, in this exemplified embodiment there is no mis-alignment issue between the via of the top via structure and the upper line structure.

FIGS. 14A, 14B and 14C are various views of the exemplary structure shown in FIGS. 13A, 13B and 13C, respectively, after forming a second 2D material layer to provide an interconnect structure in accordance with a further embodiment of the present application.

FIG. 15 is a skeleton image of the interconnect structure shown in FIG. 14C without the dielectric layer.

### DETAILED DESCRIPTION

The present application will now be described in greater detail by referring to the following discussion and drawings that accompany the present application. It is noted that the drawings of the present application are provided for illustrative purposes only and, as such, the drawings are not drawn to scale. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

The terms substantially, substantially similar, about, or any other term denoting functionally equivalent similarities refer to instances in which the difference in length, height, or orientation convey no practical difference between the definite recitation (e.g. the phrase sans the substantially similar term), and the substantially similar variations. In one embodiment, substantial (and its derivatives) denote a difference by a generally accepted engineering or manufacturing tolerance for similar devices, up to, for example, 10% deviation in value or 10° deviation in angle.

For advanced nodes (below 20 nm metal pitch), even with alternative metal interconnects such as using top via structures, the increase in both line resistance and via resistance is one of the biggest concerns. To reduce the line resistance, increasing the line height is effective, however, extra process challenges arise in both a subtractive etching process and a damascene process that can be used in providing such increased height lines. For example, increasing the line height in a subtractive etching process can cause metal etching issues especially with alternative metals such as ruthenium. In the case of a damascene process, increased line height can cause line wiggling issues. Also, the impact of mis-alignment between a via and a line on via resistance is significant in cases of small dimensions (in case where the via diameter is smaller than 10 nm). Therefore, there is a need for interconnect structures that have low line resistance and via resistance even at small dimensions for advanced nodes.

2D materials such as, for example, graphene, are effective to reduce metal line resistance due to their extremely low lateral resistance (on the order of 10⁻⁶ Ωcm or less). However, vertical resistance of 2D materials is very high and thus, via resistance should be increased significantly in cases in which a 2D material layer exists at the interface between the via and line. Also, the deposition temperature of the 2D materials is high (greater than 400° C. for most processes) and most 2D materials are not compatible to copper, Cu, interconnect processing. Therefore, when 2D materials are utilized for metal interconnect, the above challenges need to be addressed.

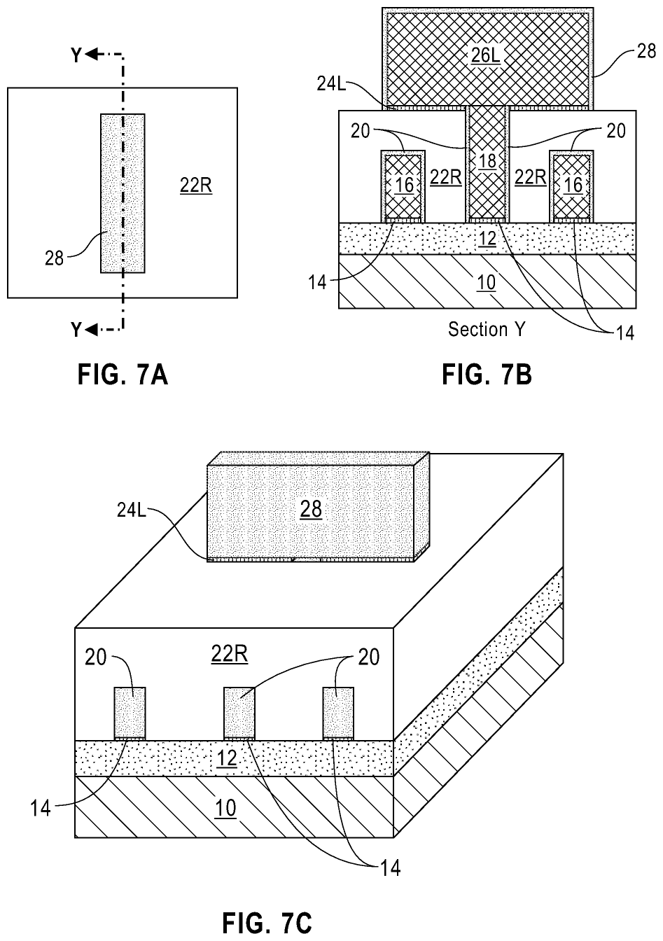

The above problems are solved by providing an interconnect structure (as shown, for example, in FIGS. 7B, 7C, 10B, 10C, 14B and 14C) that includes top via structure 18 including via 18V located on line 18L. Upper line structure 26L is located on top of the via 18V and is orientated perpendicular to the line 18L of the top via structure 18. First 2D material layer 20 is located along sidewalls of the top via structure 18 and on a topmost surface of the line 18L of the top via structure 18, and second 2D material layer 28 is located along sidewalls and a topmost surface of the upper line structure 26L. In the present application, the first 2D material layer 20 and the second 2D material layer 28 contact each other along the sidewalls of the top via structure 18 and the upper line structure 26L. This structure provides a continuous 2D material that is present on physically exposed surfaces of both the top via structure 18 (including the via 18V and line 18L) and the upper line structure 26L. The continuous 2D material provides a low line resistance and low via resistance. The low resistance is achieved since the current runs only through a lateral direction of the continuous 2D material everywhere in the structure of the present application.

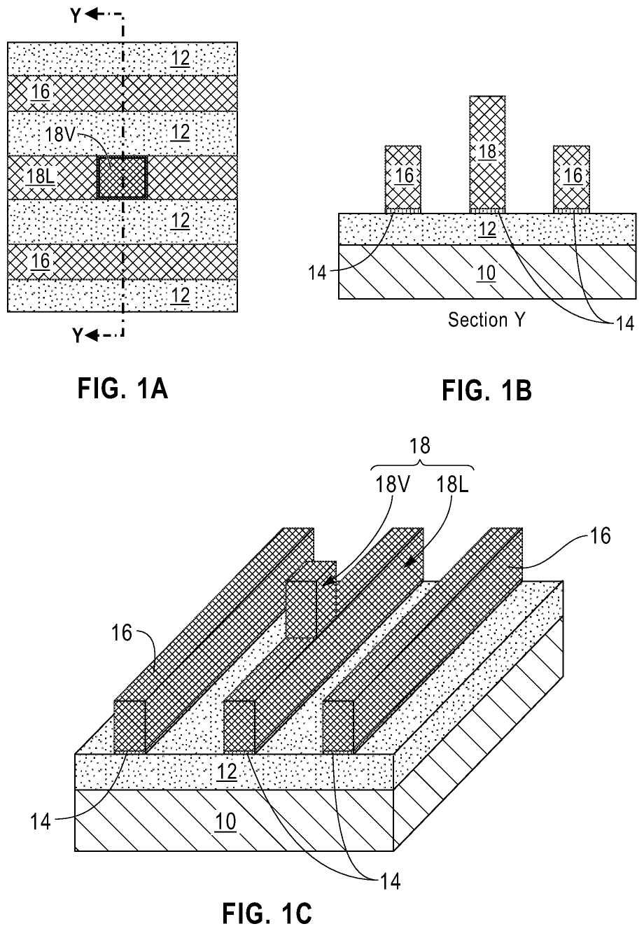

Referring first to FIGS. 1A, 1B and 1C, there are illustrated through various views an exemplary structure that can be employed in the present application. The initial structure illustrated in FIGS. 1A-1C includes a pair of line structures 16 sandwiching a top via structure 18. Although a pair of line structures 16 are described and illustrated, the present application works when no line structures 16 are formed or when more than a pair of line structures 16 are formed. Although a single top via structure 18 is described and illustrated, the present application works when a plurality of top via structures 18 are formed. Also, the present application is not limited to a configuration which includes the pair of line structures 16 sandwiching the top via structure 18 as is illustrated in the present application. Embodiments can include any configuration in which at least one top via structure 18 is present. In the present application, each line structures 16 has a length that is greater than a length of a via; vias are used to interconnect a lower level line to an upper level line. In the present application, a top via structure 18 is a contiguous structure of unitary construction that includes a via 18V that is located on a line 18L.

As is further illustrated in FIGS. 1B and 1C, the line structures 16 and the top via structure 18 are located above a front-end-of-the-line (FEOL) level 10 and a metal level 12. In some embodiments, the metal level 12 can be a middle-of-the line (MOL) level. In other embodiments, the metal level 12 can be at least one lower interconnect level of a multi-level interconnect structure. In yet further embodiments, the metal level 12 can be a combination of a MOL level and at least one lower interconnect level of a multi-level interconnect structure. The metal level 12 can include electrically conductive wiring structures (e.g., metal lines and metal vias) embedded in a dielectric material layer. The FEOL level 10 can include a semiconductor substrate having one or more semiconductor devices (such as, for example, transistors) formed thereon. The metal level 12 and the FEOL level 10 can be formed utilizing materials and techniques that are well known to those skilled in the art. So not to obscure the interconnect structure of the present application, the materials and techniques used in providing the metal level 12 and the FEOL level 10 are not described in the present application.

In some embodiments, and as is illustrated in FIGS. 1B and 1C, each line structure 16 and the top via structure 18 is located on a surface of a first diffusion barrier (or adhesion) layer 14. In some embodiments, the first diffusion barrier layer 14 can be omitted from the exemplary structure. When present, the first diffusion barrier layer 14 can be located on an uppermost surface of the metal level 12 and the first diffusion barrier layer 14 can be composed of a diffusion barrier material such as, for example, Ta, TaN, Ti, TiN, Ru, RuN, RuTa, RuTaN, W, WN or any other material that can serve as a barrier to prevent an electrically conductive material from diffusing there through. In some embodiments, a combination of diffusion barrier materials, e.g., Ta/TaN can be employed as the first diffusion barrier layer 14. The thickness of the first diffusion barrier layer 14 may vary. In one example, the thickness of the first diffusion barrier layer 14 is from 0.5 nm to 10 nm.

The line structures 16 and the top via structure 18 are composed of a first template material. In some embodiments, the first template material that provides the line structures 16 and the top via structure 18 is an electrically conductive material such as, for example, an electrically conductive metal or an electrically conductive metal alloy. Illustrative examples of electrically conductive metals that can be used in providing the lines structures 16 and the top via structure 18 include, but are not limited to, aluminum (Al), tungsten (W), cobalt (Co), ruthenium (Ru), nickel (Ni), iridium (Ir), molybdenum (Mo) or rhodium (Rh). An example of an electrically conductive alloy that can be used in providing the lines structures and the top via structure 18 includes a Cu—Al alloy. In the present application, copper metal is not typically used since it cannot be dry etched. Also, copper is a less noble metal compared to the electrically conductive metals mentioned above and thus copper can oxidize easily. In the present application, the electrically conductive metals and electrically conductive metal alloys are typically those materials that can be (a) readily etched using a dry etching process, and (b) have high melting points which allows deposition of the 2D materials at deposition temperatures of greater than 400° C. The above listed electrically conductive metals and electrically conductive metal alloys are typical interconnect materials that are used in fabricating interconnect structures. In embodiments in which the line structures 16 and the top via structure 18 are composed of an electrically conductive material, the line structures 16 and the top via structure 18 are electrically conductive structures.

In some embodiments, the first template material that provides the line structures 16 and the top via structure 18 is a non-electrically conductive material that is easy to pattern. Illustrative examples of non-electrically conductive materials that can be used in providing the line structures 16 and the top via structure 18 include, but are not limited to, amorphous silicon, and dielectric materials such as, for example, silicon dioxide. In embodiments in which the line structures 16 and top via structure 18 are composed of a non-electrically conductive material, the line structures 16 and top via structure 18 are not electrically conductive structures.

The line structures 16 and the top via structure 18 (with or without the first diffusion barrier layer 14) can be formed utilizing techniques well known to those skilled in the art. For example, a blanket layer of diffusion barrier material can be, but necessarily always, first deposited on the metal level 12. The deposition of the blanket layer of diffusion barrier material can include, for example, chemical vapor deposition (CVD), plasma enhanced chemical vapor deposition (PECVD), atomic layer deposition (ALD), physical vapor deposition (PVD), sputtering, chemical solution deposition or plating. Next, a blanket layer of the first template material (electrically conductive or non-electrically conductive) is deposited on the blanket layer of diffusion barrier material. The deposition of the blanket layer of first template material can include, for example, PVD, CVD, PECVD, sputtering, chemical solution deposition or plating. In one embodiment, a bottom-up plating process can be employed in forming the blanket layer of first template material.

The blanket layer of first template material and, if present, the blanket layer of diffusion barrier material are then patterned by lithography and etching to form tall line structures that are composed of the first template material and present on the first diffusion barrier layer 14; if the first diffusion barrier layer 14 is not used the tall line structure are present on the metal level 12. Lithography includes forming a photoresist material on a layer or stack of material layers that need to be patterned, exposing the photoresist material to a desired pattern of irradiation and thereafter developing the exposed photoresist material utilizing a conventional resist developer. The developed photoresist material has a desired pattern that is then transferred to the layer or stack of material layers that need to be patterned by etching. Etching can include dry etching and/or chemical wet etching. In an embodiment, a dry etch such as, for example, reactive ion etching (RIE), ion beam etching (IBE), plasma etching or any combination thereof can be used to transfer the pattern to the layer or stack of material layers that need to be patterned. In illustrated embodiment, the etching step etches through an entirety of the two blanket layers (or only the blanket layer of first template material). In embodiments, the etching step can stop on the metal level 12. The developed photoresist material can be removed any time after etching (including an initial etch or the entirety of the etch) utilizing a conventional photoresist removal process. A block mask (having a via shape) can then be formed on a portion or at least one of the tall line structure, and another etching process can be used to reduce the height of each of the tall line structure. After this etch, the block mask can be removed to provide the exemplary structure illustrated in FIGS. 1A-1C. It is noted that the above represents one possible technique that can be used to form the exemplary structure shown in FIGS. 1A-1C and that other techniques including a damascene process can be used.

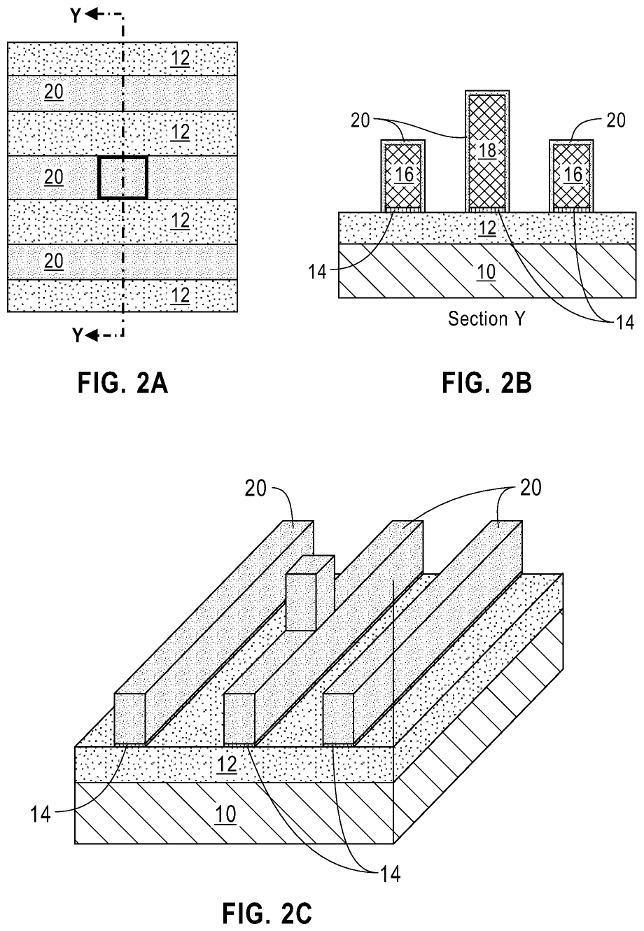

Referring now to FIGS. 2A, 2B and 2C, there are illustrated the exemplary structure shown in FIGS. 1A, 1B and 1C, respectively, after forming a first 2D material layer 20 on the pair of line structures 16 and the top via structure 18. In some embodiments, the first 2D material layer 20 is located only on the physically exposed surfaces (top and sidewalls) of each line structure 16 and the top via structure 18. The first 2D material layer 20 can be absent from the sidewalls of the first diffusion barrier layer 14 that is located beneath the line structures 16 and beneath the top via structure 18. In the present application, a 2D material refers to a crystalline solid consisting of a single layer or multiple layers of atoms. Illustrative examples of 2D materials that can be employed in the present application in providing the first 2D material layer 20 include, but are not limited to, graphene, TaS₂, MoS₂, WSe₂ or other like materials that are crystalline solids as defined above. The 2D material that can be employed is electrically conductive. In some embodiments, the first 2D material layer 20 can be formed by a selective deposition process in which the 2D material will grow only on a metal layer. In other embodiments, the first 2D material layer 20 can be formed by a non-selective deposition process, followed by an etch back process. In some embodiments, the selective or non-selective deposition can be performed at a temperature of greater than 400° C.

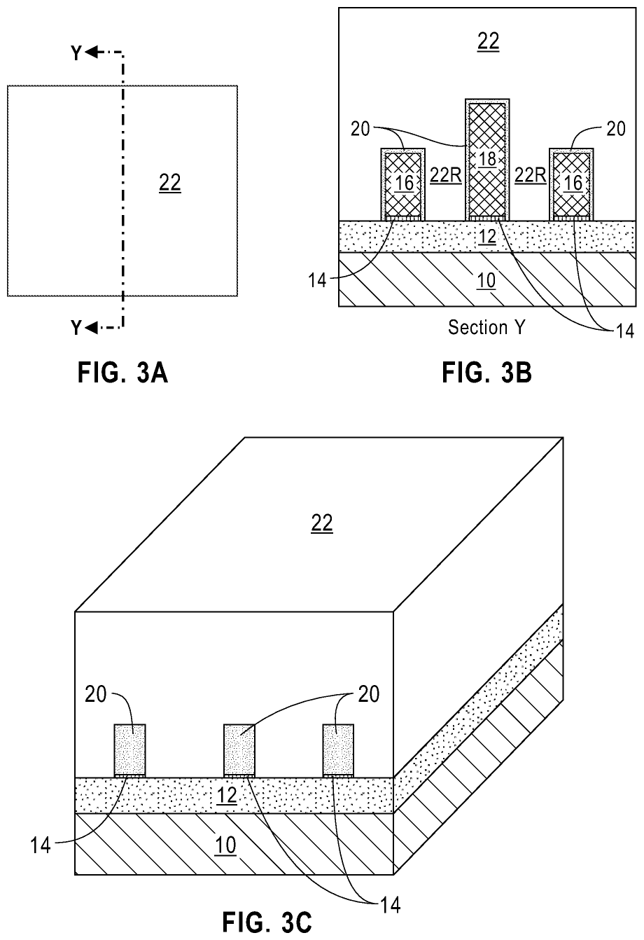

Referring now to FIGS. 3A, 3B and 3C, there are illustrated the exemplary structure shown in FIGS. 2A, 2B and 2C, respectively, after forming a dielectric layer 22. Dielectric layer 22 can be composed of any interconnect dielectric material including, for example, silicon oxide (SiOₓ), silicon nitride, undoped silicate glass (USG), fluorosilicate glass (FSG), borophosphosilicate glass (BPSG), a spin-on low-k dielectric, a chemical vapor deposition (CVD) low-k dielectric, or any combination thereof. The term “low-k” as used throughout the present application denotes a dielectric material that has a dielectric constant of less than 4.0 (all dielectric constants mentioned herein are relative to a vacuum unless otherwise noted). The interconnect dielectric material that provides dielectric layer 22 is typically composition different from the template dielectric material that can be employed. The dielectric layer 22 can be formed by a deposition process such as, for example, CVD, PECVD or spin-on coating. The dielectric layer 22 fills in the gaps that are located between the various line structures 16 and the top via structure 18. The dielectric layer 22 covers an entirety of the 2D material layer 20 that is located on a topmost surface of the via 18V of the top via structure 18.

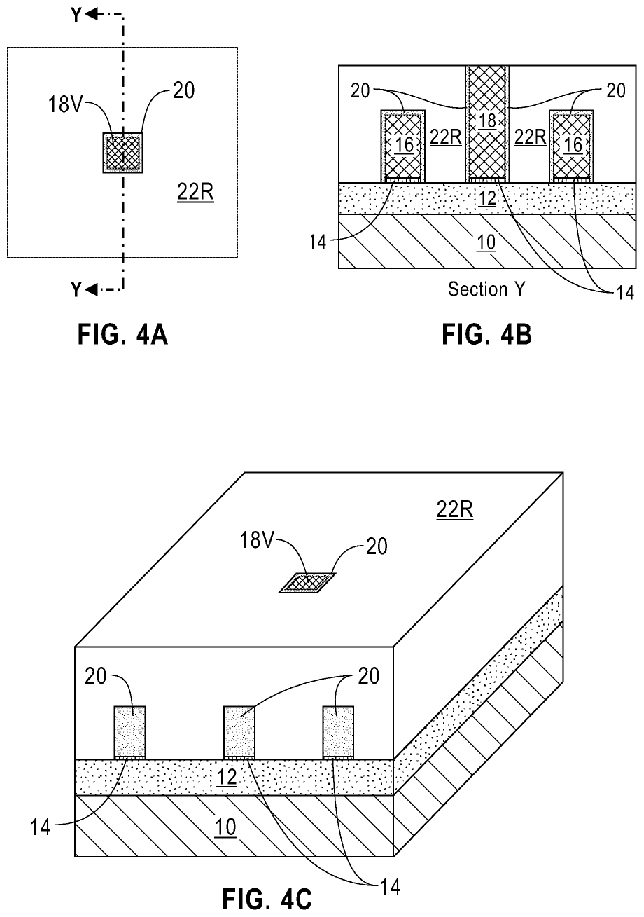

Referring now to FIGS. 4A, 4B and 4C, there are illustrated the exemplary structure shown in FIGS. 3A, 3B and 3C, respectively, after revealing a topmost surface of the top via structure 18. Although the illustrated embodiment reveals the topmost surface of the top via structure 18, this step can be used to reveal the 2D material layer 20 that is located on the topmost surface of the via 18V of the top via structure 18. In either embodiment, the revealing step includes a planarization process such as, for example, chemical mechanical polishing (CMP) or grinding. The planarization process provides recessed dielectric layer 22R.

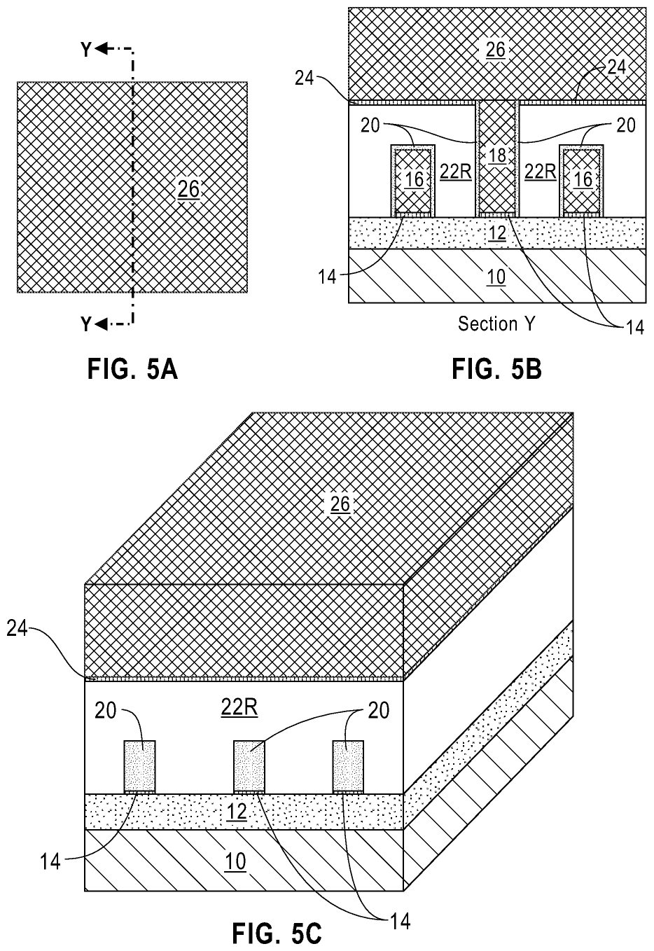

Referring now to FIGS. 5A, 5B and 5C, there are illustrated the exemplary structure shown in FIGS. 4A, 4B and 4C, respectively, after forming a diffusion barrier layer (this diffusion barrier layer represents a second diffusion barrier layer 24 that is employed in the present application) and a template material layer 26. In some embodiments, the second diffusion barrier layer 24 is omitted. When present, the second diffusion barrier layer 24 is composed of one of the diffusion barrier materials mentioned above for the first diffusion barrier layer 14. The second diffusion barrier layer 24 can be formed utilizing one of the deposition processes mentioned above in forming the first diffusion barrier layer 14.

The template material layer 26 includes one of the template materials mentioned above in forming the line structures 16 and top via structure 18. The template material that provides template material layer 26 can be compositionally the same as, or compositionally different from, the template material that provides the line structures 16 and top via structures 18. The template material layer 26 can be formed utilizing one of the deposition processes mentioned above in forming the line structures 16 and the top via structure 18.

In some embodiments, the second diffusion barrier layer 24 is formed directly on a physically exposed surface of the 2D material layer 20 that is located on the topmost surface of the via 18V of the top via structure 18. In other embodiments, the second diffusion barrier layer 24 is formed directly on a physically exposed topmost surface of the via 18V of the top via structure 18. In yet other embodiments, the template material layer 26 is formed directly on a physically exposed surface of the 2D material layer 20 that is located on the topmost surface of the via 18V of the top via structure 18. In further embodiments, the template material layer 26 is formed directly on a physically exposed topmost surface of the via 18V of the top via structure 18.

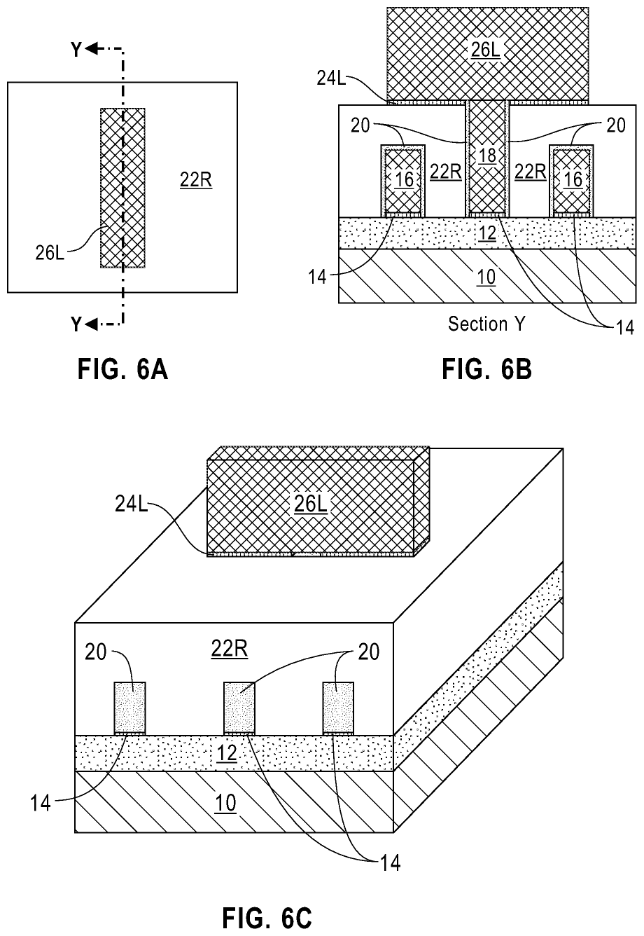

Referring now to FIGS. 6A, 6B and 6C, there are illustrated the exemplary structure shown in FIGS. 5A, 5B and 5C, respectively, after patterning the second diffusion barrier layer 24 and the template material layer 26 to provide a diffusion barrier liner 24L and upper line structure 26L; in this exemplified embodiment there is no mis-alignment issue between the via 18V of the top via structure 18 and the upper line structure 26L. That is, the upper line structure 26L covers an entirety of the via 18V of the top via structure 18. Note that upper line structure 26L runs perpendicular to each of the underlying line structures 16 and the line 18L of the top via structure 18. This patterning step includes lithography and etching as defined above.

Referring now to FIGS. 7A, 7B and 7C, there are illustrated the exemplary structure shown in FIGS. 6A, 6B and 6C, respectively, after forming a second 2D material layer 28 to provide an interconnect structure in accordance with one embodiment of the present application. The second 2D material layer 28 includes one of the 2D materials mentioned above for the first 2D material layer 20. The 2D material that provides the second 2D material layer 28 can be compositionally the same as, or compositionally different from the 2D material that provides the first 2D material layer 20. The second 2D material layer 28 can be formed by a selective deposition process or a non-selective deposition process as mentioned above for forming the first 2D material layer 20. The second 2D material layer 28 is formed on a topmost surface and along sidewalls of the upper line structure 26L.

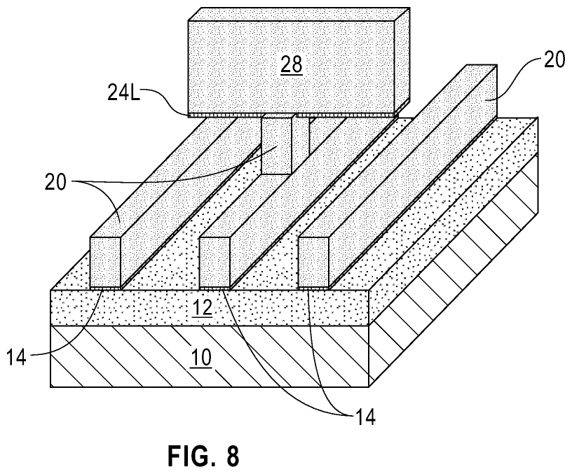

In this embodiment, the via resistance is low since the via resistance is determined by the lateral resistance of the first 2D material layer 20 that is present along the sidewalls of the via 18V of the top via structure. The second 2D material layer 28 contacts the first 2D material layer 20 that is present along the sidewalls of the via 18V of the top via structure 18. Thus, this contact between the second 2D material layer 28 and the first 2D material layer 20 provides a continuous 2D material connection along the sidewalls of the via 18V and the sidewalls of the line 18L and the upper line structure 26L. Each line structure 16 is covered with a 2D material, i.e., the first 2D material layer 20, as well. These aspects of the present application are clearly illustrated in FIG. 8 of the present application. The 2D material connection that is provided along the sidewalls of the upper line structure 26L and the top via structure 18 reduces the via resistance of the top via structure 18. In embodiments in which the top via structure 18 and/or the upper line structure 26L are composed of non-electrically conductive materials, an interconnect structure is provided by merely the first 2D material layer 20 and the second 2D material layer 28. In other embodiments in which the top via structure 18 and the upper line structure 26L are both composed of electrically conductive materials, an interconnect structure is provided that includes the first 2D material layer 20, the second 2D material layer 28, top via structure 18 and the upper line structure 26L.

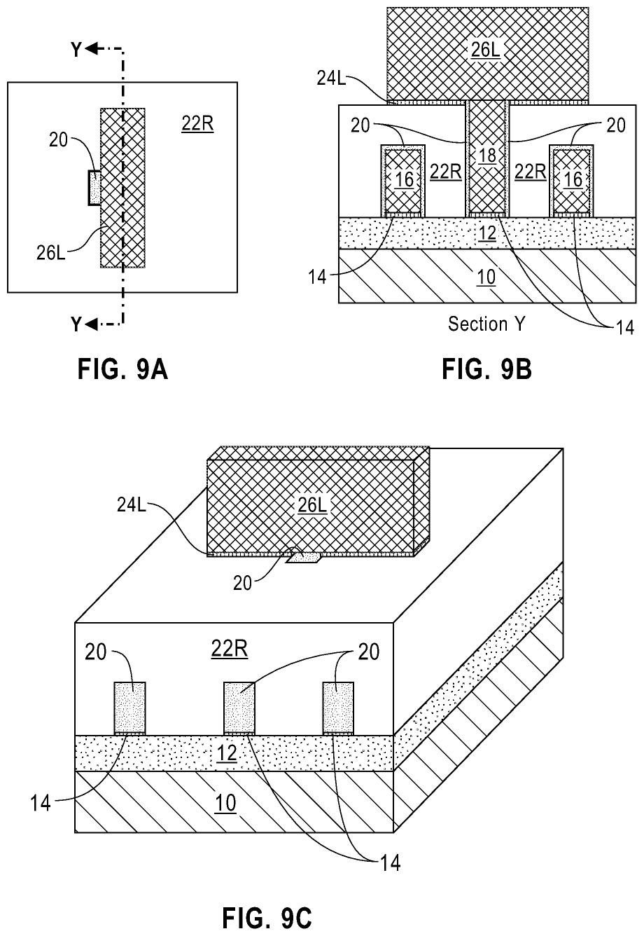

Referring now to FIGS. 9A, 9B and 9C, there are illustrated the exemplary structure shown in FIGS. 5A, 5B and 5C, respectively, after patterning the second diffusion barrier layer 24 and the template material layer 26 to provide a diffusion barrier liner 24L and upper line structure 26L; in this exemplified embodiment there is some mis-alignment issue (i.e., partially mis-aligned) between the via 18V of the top via structure 18 and the upper line structure 26L. In this embodiment, the upper line structure partially covers the via 18V of the top via structure 18. Note that upper line structure 26L runs perpendicular to each of the underlying line structures 16 and the line 18L of the top via structure 18. This patterning step includes lithography and etching as defined above.

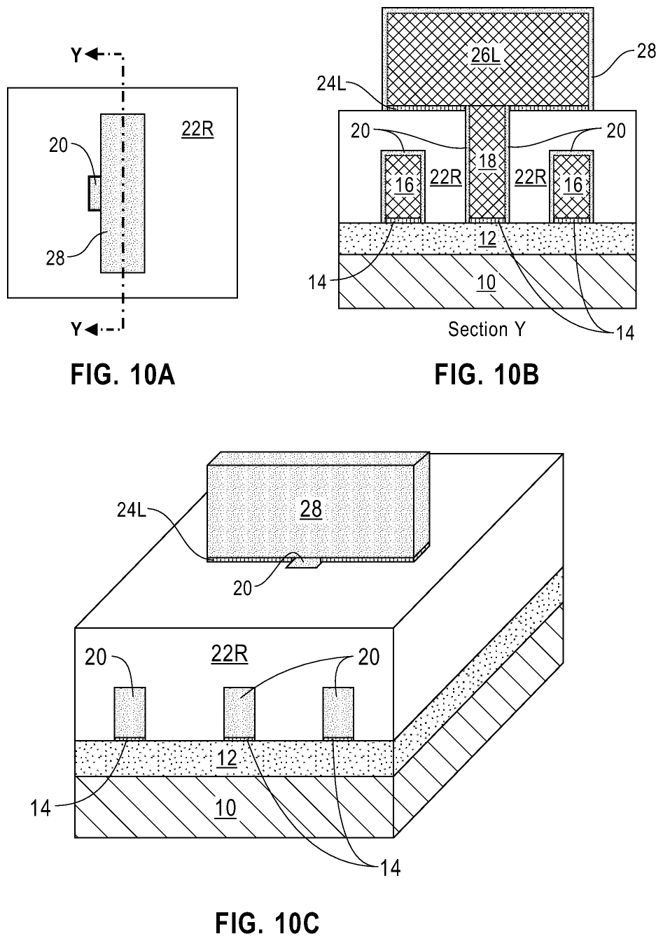

Referring now to FIGS. 10A, 10B and 10C, there are illustrated the exemplary structure shown in FIGS. 9A, 9B and 9C, respectively, after forming a second 2D material layer 28 to provide an interconnect structure in accordance with another embodiment of the present application. The second 2D material layer 28 includes one of the 2D materials mentioned above for the first 2D material layer 20. The 2D material that provides the second 2D material layer 28 can be compositionally the same as, or compositionally different from the 2D material that provides the first 2D material layer 20. The second 2D material layer 28 can be formed by a selective deposition process or non-selective deposition process as mentioned above for forming the first 2D material layer 20. The second 2D material layer 28 is formed on a topmost surface and along sidewalls of the upper line structure 26L as well as on the exposed topmost surface of the via 18V.

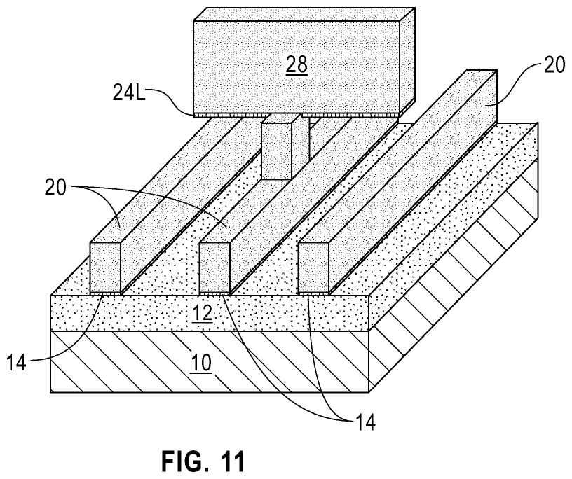

In this embodiment, the via resistance is low since the via resistance is determined by the lateral resistance of the first 2D material layer 20 that is present along the sidewalls of the via 18V of the top via structure. The second 2D material layer 28 contacts the first 2D material layer 20 that is present along the sidewalls of the via 18V of the top via structure 18V. Thus, this contact between the second 2D material layer 28 and the first 2D material layer 20 provides a continuous 2D material connection along the sidewalls of the via 18 and the sidewalls of the line 18 and the upper via structure 26L. Each line structure 16 is covered with a 2D material, i.e., the first 2D material layer 20, as well. These aspects of the present application are clearly illustrated in FIG. 11 of the present application. The 2D material connection that is provided along the sidewalls of the upper line structure 26L and the top via structure 18 reduces the via resistance of the top via structure 18. In embodiments in which the top via structure 18 and/or the upper line structure 26L are composed of non-electrically conductive materials, an interconnect structure is provided by merely the first 2D material layer 20 and the second 2D material layer 28. In other embodiments in which the top via structure 18 and the upper line structure 26L are both composed of electrically conductive materials, an interconnect structure is provided that includes the first 2D material layer 20, the second 2D material layer 28, top via structure 18 and the upper line structure 26L.

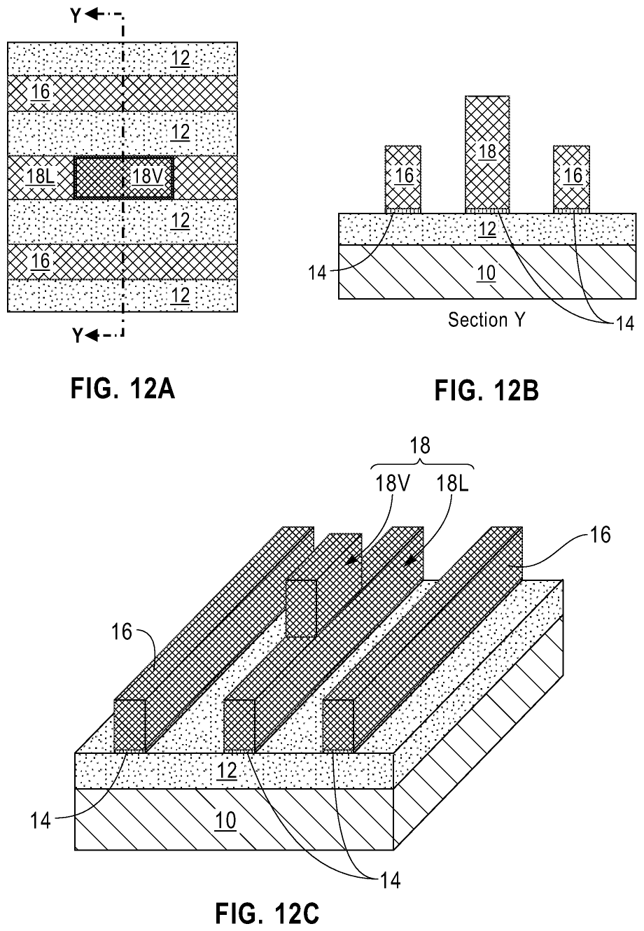

Referring now to FIGS. 12A, 12B and 12C, there are illustrated another exemplary structure that can be employed in the present application. The another exemplary structure illustrated in FIGS. 12A-12C includes a pair of line structures 16 sandwiching a top via structure 18. In this embodiment, the top via structure 18 has an elongated via 18V as compared to the via 18V of the top via structure 18 shown in FIGS. 1A, 1B and 1C. The another exemplary structure illustrated in FIGS. 12A-12C also includes optional first diffusion barrier layer 14 (can be omitted in some embodiments), metal level 12 and FEOL level 10 all of which have been described herein above in regard to FIGS. 1A-1C. The line structures 16 and top via structure 18 of this embodiment include materials as mentioned above in regard to the line structures 16 and top via structure 18 described above. The line structures 16 and top via structure 18 of this embodiment can be formed utilizing the technique mentioned above in forming the line structures 16 and top via structure 18 shown in FIGS. 1A-1C. The elongated via 18V of the top via structure provides an interconnect structure having a self-aligned via.

Although a pair of line structures 16 are described and illustrated, the present application works when no line structures 16 are formed or when more than a pair of line structures 16 are formed. Although a single top via structure 18 is described and illustrated, the present application works when a plurality of via structures 18 are formed. Also, the present application is not limited to a configuration which includes the pair of line structures 16 sandwiching the top via structure 18 as is illustrated in the present application. Embodiments can include any configuration in which at least one top via structure 18 is present. In the present application, each line structures 16 has a length that is greater than a length of a via; vias are used to interconnect a lower level line to an upper level line. In the present application, a top via structure 18 is a contiguous structure of unitary construction that includes a via 18V that is located on a line 18L.

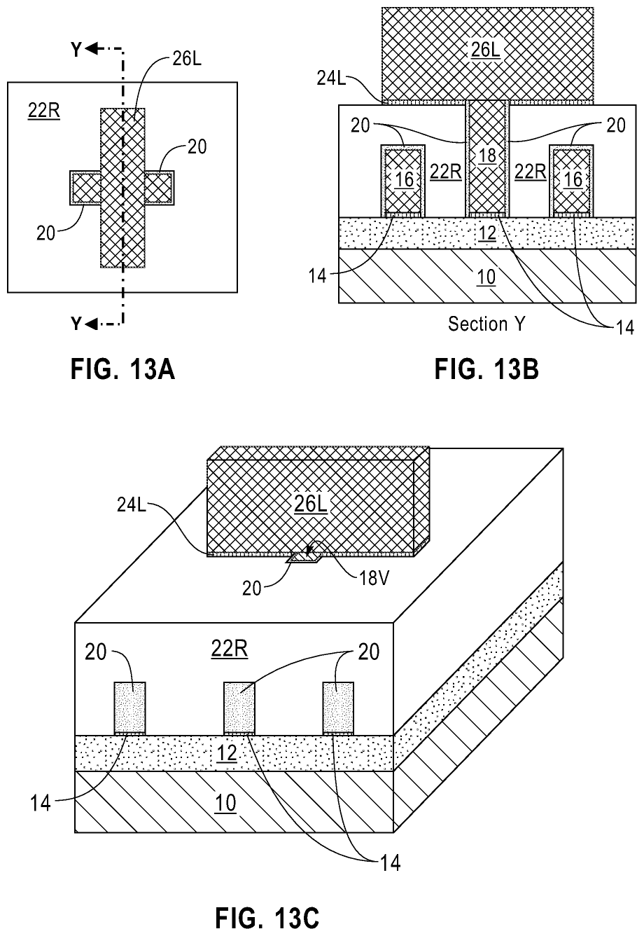

Referring now to FIGS. 13A, 13B and 13C, there are illustrated the exemplary structure shown in FIGS. 12A, 12B and 12C, respectively, after performing the processing steps shown in FIGS. 2A-6C above, in this exemplified embodiment there is no mis-alignment issue between the via 18V of the top via structure 18 and the upper line structure 26L. In this embodiment, the elongated via 18V of the top via structure 18 is designed to have a greater width than the width of the upper liner structure 26L; the facilitates alignment between the upper line structure 261 and the via 18V of the top via structure 18.

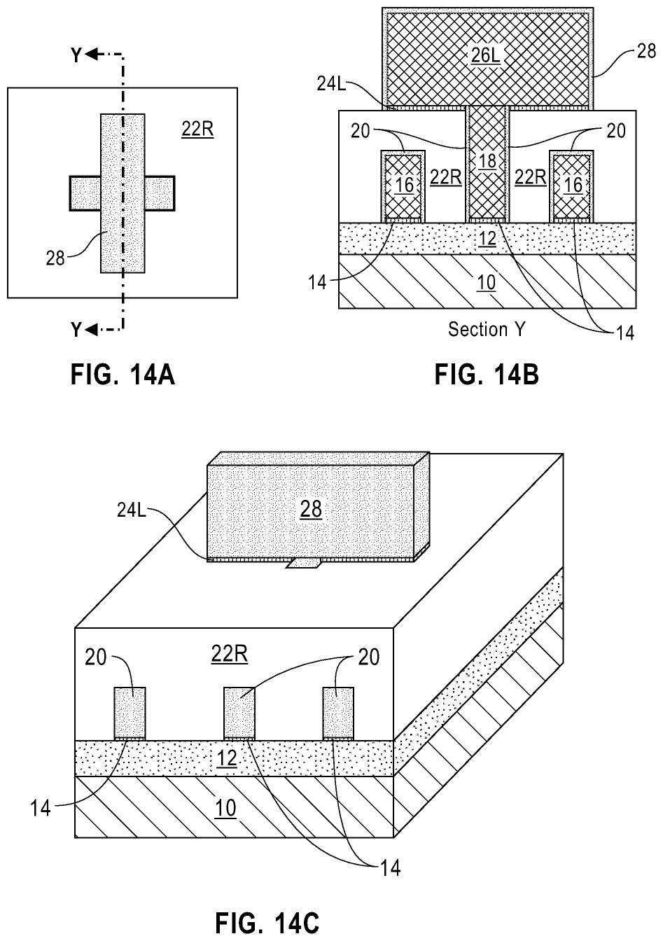

Referring now to FIGS. 14A, 14B and 14C, there are illustrated the exemplary structure shown in FIGS. 13A, 13B and 13C, respectively, after forming a second 2D material layer 28 to provide an interconnect structure in accordance with a further embodiment of the present application. The second 2D material layer 28 includes one of the 2D materials mentioned above for the first 2D material layer 20. The 2D material that provides the second 2D material layer 28 can be compositionally the same as, or compositionally different from the 2D material that provides the first 2D material layer 20. The second 2D material layer 28 can be formed by a selective deposition process or a non-selective deposition process as mentioned above for forming the first 2D material layer 20. The second 2D material layer 28 is formed on a topmost surface and along sidewalls of the upper line structure 26L as well as on the exposed topmost surface of the via 18V.

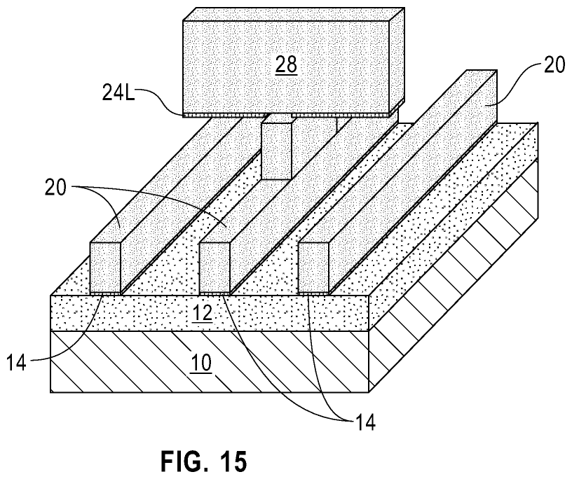

In this embodiment, the upper line structure 26L lands on a portion of the elongated via 18V of the top via structure. Also, and in this embodiment, the via resistance is low since the via resistance is determined by the lateral resistance of the first 2D material layer 20 that is present along the sidewalls of the via 18V of the top via structure. The second 2D material layer 28 contacts the first 2D material layer 20 that is present along the sidewalls of the via 18V of the top via structure 18V. Thus, this contact between the second 2D material layer 28 and the first 2D material layer 20 provides a continuous 2D material connection along the sidewalls of the via 18 and the sidewalls of the line 18 and the upper via structure 26L. Each line structure 16 is covered with a 2D material as well. These aspects of the present application are clearly illustrated in FIG. 15 of the present application. The 2D material connection that is provided along the sidewalls of the upper line structure 26L and the top via structure 18 reduces the via resistance of the top via structure 18. In embodiments in which the top via structure 18 and/or the upper line structure 26L are composed of non-electrically conductive materials, an interconnect structure is provided by merely the first 2D material layer 20 and the second 2D material layer 28. In other embodiments in which the top via structure 18 and the upper line structure 26L are both composed of electrically conductive materials, an interconnect structure is provided that includes the first 2D material layer 20, the second 2D material layer 28, top via structure 18 and the upper line structure 26L.

While the present application has been particularly shown and described with respect to preferred embodiments thereof, it will be understood by those skilled in the art that the foregoing and other changes in forms and details may be made without departing from the spirit and scope of the present application. It is therefore intended that the present application not be limited to the exact forms and details described and illustrated, but fall within the scope of the appended claims.

What is claimed is:

1. An interconnect structure comprising:
a top via structure comprising a via located on a line;
an upper line structure located on top of the via and orientated perpendicular to the line of the top via structure;
a first two dimensional (2D) material layer located along sidewalls of the top via structure and on a topmost surface of the line of the top via structure; and
a second 2D material layer located along sidewalls and a topmost surface of the upper line structure, wherein the first 2D material layer and the second 2D material layer contact each other along the sidewalls of the top via structure and the upper line structure.

2. The interconnect structure of claim 1, wherein the upper line structure is aligned to the via of the top via structure.

3. The interconnect structure of claim 1, wherein the upper line structure is mis-aligned to the via of the top via structure.

4. The interconnect structure of claim 1, wherein each of the first 2D material layer and the second 2D material layer comprises an electrically conductive material.

5. The interconnect structure of claim 4, wherein the first 2D material layer is composed of a 2D material that is compositionally the same as a 2D material that provides the second 2D material layer.

6. The interconnect structure of claim 4, wherein the first 2D material layer is composed of a 2D material that is compositionally different than a 2D material that provides the second 2D material layer.

7. The interconnect structure of claim 4, wherein the first 2D material layer and the second 2D material layer are composed of graphene, TaS₂, MoS₂, or WSe₂.

8. The interconnect structure of claim 1, wherein each of the top via structure and the upper line structure is composed of an electrically conductive metal or an electrically conductive metal alloy.

9. The interconnect structure of claim 1, wherein each of the top via structure and the upper line structure is composed of a non-conductive material.

10. The interconnect structure of claim 9, wherein the non-conductive material is composed of amorphous silicon.

11. The interconnect structure of claim 9, wherein the non-conductive material comprises a dielectric material.

12. The interconnect structure of claim 1, further comprising a line structure located adjacent to the line of the top via structure, wherein the line structure is covered with the first 2D material layer.

13. The interconnect structure of claim 1, further comprising a front-end-of-the-line (FEOL) level and a metal level located beneath the top via structure.

14. The interconnect structure of claim 13, further comprising a diffusion barrier layer separating the top via structure from the metal level.

15. The interconnect structure of claim 1, further comprising a dielectric layer embedding the top via structure and the 2D material layer that is present on the top via structure.

16. An interconnect structure comprising:
a top via structure comprising a via located on a line, wherein the via and line are composed of an electrically conductive material;
an upper line structure located on top of the via and orientated perpendicular to the line of the top via structure; and
a continuous 2D material covering an entirety of the upper line structure and the top via structure.

17. The interconnect structure of claim 16, wherein continuous 2D material is composed of graphene, TaS₂, MoS₂, or WSe₂.

18. An interconnect structure comprising:
a top via structure comprising a via located on a line, wherein the via and line are composed of a non-conductive material;
an upper line structure located on top of the via and orientated perpendicular to the line of the top via structure; and
a continuous 2D material covering an entirety of the upper line structure and the top via structure.

19. The interconnect structure of claim 18, wherein the continuous 2D material is composed of graphene, TaS₂, MoS₂, or WSe₂.

20. The interconnect structure of claim 18, wherein the non-conductive material is composed of amorphous silicon.
